(19) United States
(12) Patent Application Publication
(10) Pub. No.: US 2025/0277869 A1
(43) Pub. Date: Sep. 4, 2025

(54) METHOD FOR IN-VEHICLE STATE ESTIMATION CONSIDERING VOLTAGE FADE

(71) Applicant: GM Global Technology Operations LLC, Detroit, MI (US)

(72) Inventors: Taylor Reed Garrick, Bloomfield Hills, MI (US); Brian J. Koch, Berkley, MI (US); Mingxing Zhou, Troy, MI (US); Yangbing Zeng, Troy, MI (US)

(21) Appl. No.: 18/594,620

(22) Filed: Mar. 4, 2024

(51) Int. Cl. G01R 31/396; G01R 31/367; G01R 31/3835; G01R 31/385; H01M 10/44; H01M 10/48

(52) U.S. Cl. CPC G01R 31/396; G01R 31/367; G01R 31/3835; G01R 31/386; H01M 10/446; H01M 10/482

(57) ABSTRACT

A vehicle includes a system that performs a method for operating the vehicle. A processor obtains an initial voltage fade state of a battery of the vehicle and a model of an initial state of the battery of the vehicle, commences a charging operation of the battery, measure a terminal voltage of the battery while charging, updates the model during the charging operation using the terminal voltage, ends the charging operation, obtains measurements of a cathode voltage after the charging operation has ended, determines a maximum cathode voltage from the measurements, determines an updated voltage fade state of the battery based on the maximum cathode voltage, selects a relation between cathode voltage and lithiation state based on the updated voltage fade state, calculates a state of lithiation of a cathode from the maximum cathode voltage using the selected relation, and operates the vehicle based on the updated voltage fade state.

### INTRODUCTION

The subject disclosure relates to determining a state of a battery pack for a vehicle and, in particular, to a system and method for determining a fade state of the battery pack.

Electric vehicles use electric batteries as a power source. The electric batteries can be Lithium Manganese rich batteries, such as Lithium-Manganese-Oxide (LiMnO) batteries. In Lithium Manganese rich batteries, the thermodynamic relationship between the equilibrium potential and the material state of the lithiation varies over life. This variation can be attributed to gradual structural changes in the active material over the life of the battery. A capacity fade state of the battery is indicative of a remaining capacity of the battery and can be used to determine a remaining life of the battery. Accordingly, it is desirable to provide a method for determining a fade state of the battery based on measurable parameters of the battery.

### SUMMARY

In one exemplary embodiment, a method of operating a vehicle is disclosed. The method includes obtaining an initial voltage fade state of a battery of the vehicle and a model of an initial state of the battery of the vehicle, commencing a charging operation of the battery, measuring a terminal voltage of the battery while charging, updating the model of the battery during the charging operation using the terminal voltage, ending the charging operation, obtaining a plurality of measurements of a cathode voltage after the charging operation has ended, determining a maximum cathode voltage from the plurality of measurements, determining an updated voltage fade state of the battery based on the maximum cathode voltage, selecting a relation between cathode voltage and lithiation state based on the updated voltage fade state, calculating a state of lithiation of a cathode from the maximum cathode voltage using the selected relation, and operating the vehicle based on the updated voltage fade state.

In addition to one or more of the features described herein, wherein the model further includes a positive electrode model representative of a cathode of the battery and a negative electrode model representative of an anode of the battery, the method further including updating the positive electrode model and the negative electrode model during the charging operation.

In addition to one or more of the features described herein, the method further includes determining an open-circuit voltage of the cathode from the terminal voltage and determining the lithiation state of the cathode from the open-circuit voltage of the cathode using the selected relation.

In addition to one or more of the features described herein, one of the positive electrode model and the negative electrode model includes a state variable, the state variable including at least one of an open-circuit voltage, a hysteresis voltage, and an ohmic resistance.

In addition to one or more of the features described herein, one of the positive electrode model and the negative electrode model includes a dynamic parameter, the dynamic parameter including a time constant indicative of a response of the battery to an applied load.

In addition to one or more of the features described herein, the method further includes updating the state variable and the dynamic parameter using a Kalman filter.

In addition to one or more of the features described herein, operating the vehicle further includes limiting an amount of current supplied from the battery to the vehicle based on one of the updated voltage fade state and the state of lithiation.

In another exemplary embodiment, a system for operating a vehicle is disclosed. The system includes a processor. The processor is configured to obtain an initial voltage fade state of a battery of the vehicle and a model of an initial state of the battery of the vehicle, commence a charging operation of the battery, measure a terminal voltage of the battery while charging, update the model of the battery during the charging operation using the terminal voltage, end the charging operation, obtain a plurality of measurements of a cathode voltage after the charging operation has ended, determine a maximum cathode voltage from the plurality of measurements, determine an updated voltage fade state of the battery based on the maximum cathode voltage, select a relation between cathode voltage and lithiation state based on the updated voltage fade state, calculate a state of lithiation of a cathode from the maximum cathode voltage using the selected relation, and operate the vehicle based on the updated voltage fade state.

In addition to one or more of the features described herein, the model further includes a positive electrode model representative of a cathode of the battery and a negative electrode model representative of an anode of the battery, further including updating the positive electrode model and the negative electrode model during the charging operation.

In addition to one or more of the features described herein, the processor is further configured to determine an open-circuit voltage of the cathode from the terminal voltage and determining the lithiation state of the cathode from the open-circuit voltage of the cathode using the selected relation.

In addition to one or more of the features described herein, one of the positive electrode model and the negative electrode model includes a state variable, the state variable including at least one of an open-circuit voltage, a hysteresis voltage, and an ohmic resistance.

In addition to one or more of the features described herein, one of the positive electrode model and the negative electrode model includes a dynamic parameter, the dynamic parameter including a time constant indicative of a response of the battery to an applied load.

In addition to one or more of the features described herein, the processor is further configured to update the state variable and the dynamic parameter using a Kalman filter.

In addition to one or more of the features described herein, the processor is further configured to operate the vehicle by limiting an amount of current supplied from the battery to the vehicle based on one of the updated voltage fade state and the state of lithiation.

In another exemplary embodiment, a vehicle is disclosed. The vehicle includes a processor. The processor is configured to obtain an initial voltage fade state of a battery of the vehicle and a model of an initial state of the battery of the vehicle, commence a charging operation of the battery, measure a terminal voltage of the battery while charging, update the model of the battery during the charging operation using the terminal voltage, end the charging operation, obtain a plurality of measurements of a cathode voltage after the charging operation has ended, determine a maximum cathode voltage from the plurality of measurements, determine an updated voltage fade state of the battery based on the maximum cathode voltage, select a relation between cathode voltage and lithiation state based on the updated voltage fade state, calculate a state of lithiation of a cathode from the maximum cathode voltage using the selected relation, and operate the vehicle based on the updated voltage fade state.

In addition to one or more of the features described herein, the model further includes a positive electrode model representative of a cathode of the battery and a negative electrode model representative of an anode of the battery, further including updating the positive electrode model and the negative electrode model during the charging operation.

In addition to one or more of the features described herein, the processor is further configured to determine an open-circuit voltage of the cathode from the terminal voltage and determining the lithiation state of the cathode from the open-circuit voltage of the cathode using the selected relation.

In addition to one or more of the features described herein, one of the positive electrode model and the negative electrode model includes a state variable, the state variable including at least one of an open-circuit voltage, a hysteresis voltage, and an ohmic resistance.

In addition to one or more of the features described herein, one of the positive electrode model and the negative electrode model includes a dynamic parameter, the dynamic parameter including a time constant indicative of a response of the battery to an applied load.

In addition to one or more of the features described herein, the processor is further configured to update the state variable and the dynamic parameter using a Kalman filter.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 shows an embodiment of a vehicle in accordance with an exemplary embodiment;

FIG. 2 shows an electrical system of the vehicle;

FIG. 3 shows a view of a schematic illustration of an electrochemical battery cell of the power source, in a disassembled state;

FIG. 4 shows a system model for the electrochemical battery cell;

FIG. 5 shows a view of the system model that includes a reference electrode;

FIG. 6 shows a detailed view of the positive electrode model, in an illustrative embodiment;

FIG. 7 shows a detailed view of the negative electrode model, in an illustrative embodiment;

FIG. 8 is a flowchart of a method of determining a voltage fade state of a battery cell after a charging operation, in an embodiment;

FIG. 9 is a flowchart of a method for determining a voltage fade state of a battery cell from the maximum cathode voltage;

FIG. 10 shows a graph demonstrating a difference between a capacity fade and a voltage fade; and

FIG. 11 shows a graph relating cathode potential to reversible capacity of the battery cell.

### DETAILED DESCRIPTION

The following description is merely exemplary in nature and is not intended to limit the present disclosure, its application or uses. It should be understood that throughout the drawings, corresponding reference numerals indicate like or corresponding parts and features. As used herein, the term module refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

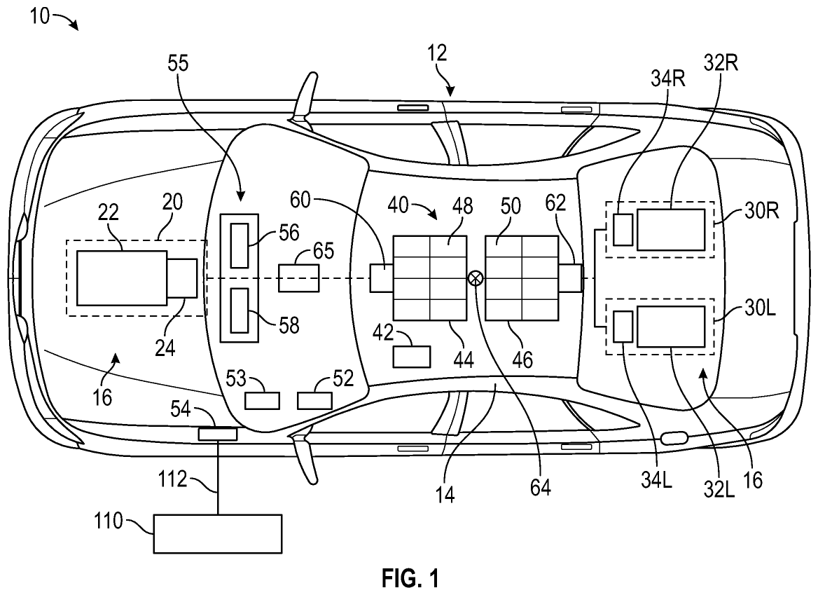

In accordance with an exemplary embodiment, FIG. 1 shows an embodiment of a vehicle 10, which includes a vehicle body 12 defining, at least in part, an occupant compartment 14. The vehicle body 12 also supports various vehicle subsystems including a propulsion system 16, and other subsystems to support functions of the propulsion system 16 and other vehicle components, such as a braking subsystem, a suspension system, a steering subsystem, and others.

The vehicle 10 may be an electrically powered vehicle (EV), a hybrid vehicle or any other vehicle. In an embodiment, the vehicle 10 is an electric vehicle that includes multiple motors and/or drive systems. The vehicle 10 can be a car, a truck, a van, a bus, a motorcycle, or other type of automobile. Any number of drive units may be included, such as one or more drive units for applying torque to front wheels (not shown) and/or to rear wheels (not shown). The drive units are controllable to operate the vehicle 10 in various operating modes, such as a normal mode, a high-performance mode (in which additional torque is applied), all-wheel drive (“AWD”), front-wheel drive (“FWD”), rear-wheel drive (“RWD”) and others.

For example, the propulsion system 16 is a multi-drive system that includes a front drive unit 20 for driving front wheels, and rear drive units for driving rear wheels. The front drive unit 20 includes a front electric motor 22 and a front inverter 24 (e.g., front power inverter module or FPIM), as well as other components such as a cooling system. A left rear drive unit 30L includes a left rear electric motor 32L and a left rear inverter 34L. A right rear drive unit 30R includes a right rear electric motor 32R and a right rear inverter 34R. The front inverter 24, left rear inverter 34L and right rear inverter 34R (e.g., power inverter units or PIMs) each convert direct current (DC) power from a high voltage (HV) battery system 40 to poly-phase (e.g., two-phase, three-phase, six-phase, etc.) alternating current (AC) power to drive the front electric motor 22 the left rear electric motor 32L and the right rear electric motor 32R.

As shown in FIG. 1, the drive systems feature separate electric motors. However, embodiments are not so limited. For example, instead of separate motors, multiple drives can be provided by a single machine that has multiple sets of windings that are physically independent.

As also shown in FIG. 1, the drive systems are configured such that the front electric motor 22 drives the front wheels (not shown), and the left rear electric motor 32L and right rear electric motor 32R drive the rear wheels (not shown). However, embodiments are not so limited, as there may be any number of drive systems and/or motors at various locations (e.g., a motor driving each wheel, twin motors per axle, etc.). In addition, embodiments are not limited to a dual drive system, as embodiments can be used with a vehicle having any number of motors and/or power inverters.

In the propulsion system 16, the front drive unit 20, left rear drive unit 30L and right rear drive unit 30R are electrically connected to the battery system 40. The battery system 40 may also be electrically connected to other electrical components (also referred to as “electrical loads”), such as vehicle electronics (e.g., via an auxiliary power module or APM 42), heaters, cooling systems and others. The battery system 40 may be configured as a rechargeable energy storage system (RESS).

In an embodiment, the battery system 40 includes a plurality of separate battery assemblies, in which each battery assembly can be independently charged and can be used to independently supply power to a drive system or systems. For example, the battery system 40 includes a first battery assembly such as a first battery pack 44 connected to the front inverter 24, and a second battery pack 46. The first battery pack 44 includes a plurality of battery modules 48, and the second battery pack 46 includes a plurality of battery modules 50. Each battery module 48, 50 includes a number of individual cells (not shown).

Each of the front electric motor 22 and the left rear electric motor 32L and right rear electric motor 32R is a three-phase motor having three phase motor windings. However, embodiments described herein are not so limited. For example, the motors may be any poly-phase machines supplied by poly-phase inverters, and the drive units can be realized using a single machine having independent sets of windings.

The battery system 40 and/or the propulsion system 16 includes a switching system having various switching devices for controlling operation of the first battery pack 44 and second battery pack 46, and selectively connecting the first battery pack 44 and second battery pack 46 to the front drive unit 20, left rear drive unit 30L and right rear drive unit 30R. The switching devices may also be operated to selectively connect the first battery pack 44 and the second battery pack 46 to a charging system. The charging system can be used to charge the first battery pack 44 and the second battery pack 46, and/or to supply power from the first battery pack 44 and/or the second battery pack 46 to charge another energy storage system (e.g., vehicle-to-vehicle (V2V) and/or vehicle-to-everything (V2X) charging). The charging system includes one or more charging modules. For example, a first onboard charging module (OBCM) 52 is electrically connected to a charge port 54 for charging to and from an AC system or device, such as a utility AC power supply. A second OBCM 53 may be included for DC charging (e.g., DC fast charging or DCFC). As shown in FIG. 1, the utility AC power supply is a charging station 110 that is connected to the charge port 54 via a cord 112.

In an embodiment, the switching system includes a first switching device 60 that selectively connects to the first battery pack 44 to the front inverter 24, left rear inverter 34L and right rear inverter 34R, and a second switching device 62 that selectively connects the second battery pack 46 to the front inverter 24, left rear inverter 34L and right rear inverter 34R. The switching system also includes a third switching device 64 (also referred to as a “battery switching device”) for selectively connecting the first battery pack 44 to the second battery pack 46 in series.

Any of various controllers can be used to control functions of the electrical system of the vehicle, including the battery system 40, the switching system the drive units, etc. A controller 65 includes any suitable processing device or unit and may use an existing controller such as a drive system controller, an RESS controller, and/or controllers in the drive system. For example, a controller 65 may be included for controlling switching and drive control operations as discussed herein.

The controller 65 may include processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality. The controller 65 may include a non-transitory computer-readable medium that stores instructions which, when processed by one or more processors of the controller 65, implement a method of determining a voltage fade state of a battery pack during a charging operation, according to one or more embodiments detailed herein.

The vehicle 10 also includes a computer system 55 that includes one or more processing devices 56 and a user interface 58. The computer system 55 may communicate with the charging system controller, for example, to provide commands thereto in response to a user input. The various processing devices, modules and units may communicate with one another via a communication device or system, such as a controller area network (CAN) or transmission control protocol (TCP) bus.

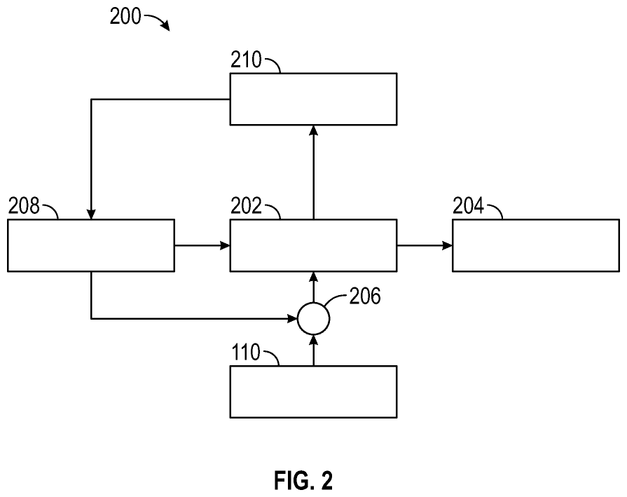

FIG. 2 shows an electrical system 200 of the vehicle 10. The electrical system 200 includes power source 202 that is discharged as it powers a load 204. The load includes a propulsion system load. The power source 202 is made up of an array of electrochemical battery cells. The battery cells are recharged by the charging station 110. Operation of the charging station 110 is controlled by a switch 206. A controller 208 controls operation of the switch 206. Sensors 210 measure various parameters of the battery cells, such as a terminal voltage signal (VT) a temperature (T) of the battery, etc. The controller 208 processes the measured parameters according to the methods disclosed herein to determine a state of lithiation of the battery cells and/or a life state of the battery cells of the power source 202. The controller 208 controls operation of the battery pack based on the state of lithiation and/or the voltage fade state.

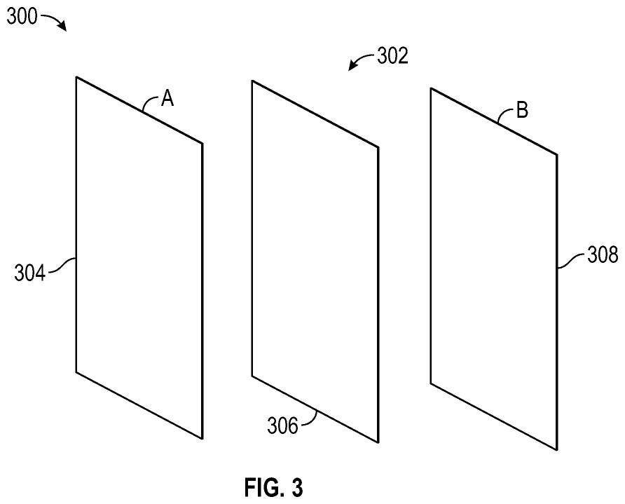

FIG. 3 shows a view 300 of a schematic illustration of an electrochemical battery cell 302 of the power source 202, in a disassembled state. The electrochemical battery cell 302 includes one or more cathodes 304, one or more separators 306, and one or more anodes 308. Each separator 306 is arranged between a cathode 304 and an anode 308. The one or more cathodes 304, the one or more separators 306, and the one or more anodes 308 are arranged in a stack. Each cathode 304 is composed of a first set of electroactive materials and the anode 308 is composed of a second set of electroactive materials. An electroactive material is a material that can accept charged particles and release charged particles. A set of electroactive materials can be a single material or a blend of materials. For example, the one or more anodes 308 can be a blend of graphite and silicon. The one or more cathodes 304 can be a blend of cobalt cathode (NMC) and a cobalt-free manganese-rich cathode (LMR). In an embodiment, a cathode 304 can be made of a Lithium Manganese rich material, such as Lithium Manganese Oxide, or other suitable material, and an anode 308 can be made of graphite. The cathode 304 connects to a first terminal A and the anode 308 connects to a second terminal B. A terminal voltage V_{T} can be measured across the battery cell between the first terminal A and the second terminal B. The terms “cathode” and “positive electrode” can be used interchangeably, and the terms “anode” and “negative electrode” can be used interchangeably. A capacity fade state of the battery measures a level of degradation of the battery or a remaining capacity of the battery. The voltage fade state is related to the voltage fade during normal use of the battery, whereas a capacity fade is related to a loss of active material of the battery due to various side reactions or mechanical stresses in the active material. The voltage fade state is linked to the life state. Voltage fade state and life state are numbers between 0 and 1 and the sum of the voltage fade state and the life state is defined as equal to 1. A state of charge of the battery indicates an amount of lithiation of the cathode 304 and of the anode 308.

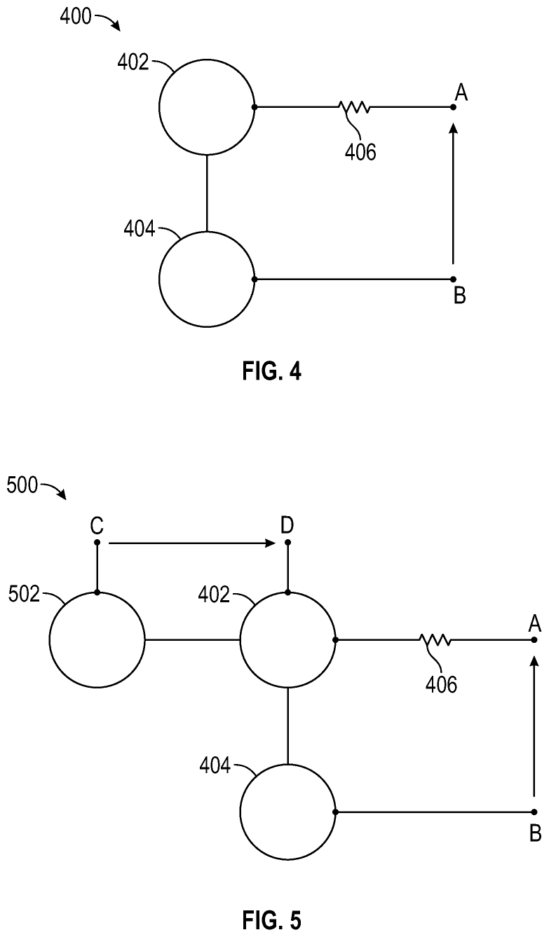

FIG. 4 shows a system model 400 for the electrochemical battery cell 302. The system model 400 includes a positive electrode model 402 representative of the cathode 304 and a negative electrode model 404 representative of the anode 308. A system resistance 406 (R_{sys}) includes a resistance of the battery cell due to internal welds, leads, current collectors, etc. The system resistance 406 is shown between the positive electrode model 402 and a first terminal node A. A terminal voltage V_{T} of the battery cell can be measured between the first terminal node A and a second node B connected to the negative electrode model 404.

FIG. 5 shows a view 500 of the system model 400 that includes a reference electrode 502. The reference electrode 502 includes a third terminal node C and the positive electrode model 402 includes a fourth terminal node D. A cathode voltage V_{P,sense} can be measured between the third terminal node C and the fourth terminal node D during a charging event. The reference electrode 502 can be placed in contact with the cathode, as represented in FIG. 5. Alternatively, the reference electrode 502 can be placed in contact with the anode. When placed in contact with the anode, the reference electrode 502 is used to explicitly measure the anode potential and the cathode potential is calculated by adding the anode potential to the terminal voltage of the battery.

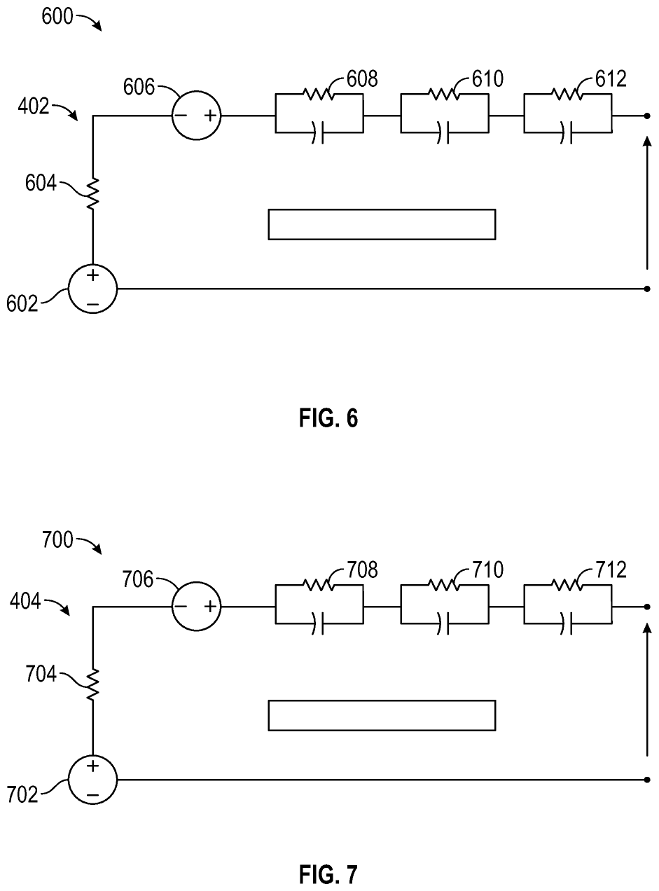

FIG. 6 shows a detailed view 600 of the positive electrode model 402, in an illustrative embodiment. The positive electrode model 402 includes various state variables and dynamic parameters. The state variables include voltages present at the cathode 304 during operation of the battery cell, such as a positive electrode open-circuit voltage 602 (V_{OCV,P}), a positive electrode ohmic resistance 604 (V_{ohmic,P}) (i.e., a voltage loss at the positive electrode due to an ohmic resistance) and a positive electrode hysteresis voltage (V_{hys,p}) 606 The positive electrode ohmic resistance 604 is related to an ohmic resistance of the cathode 304 and the positive electrode hysteresis voltage 606 results from hysteresis effects in the cathode. The positive electrode open-circuit voltage 602 V_{OCV,P} can be determined by measuring the cathode potential V_{P} with respect to the reference electrode 502 under a no load equilibrium condition. The dynamic parameters can represent responses of the cathode 304 to an applied load during charging. The responses can result from electrochemical processes that occur during charging. For illustrative purposes, the dynamic parameters are time constants represented by resistor-capacitor pairs 608, 610 and 612.

FIG. 7 shows a detailed view 700 of the negative electrode model 404, in an illustrative embodiment. The negative electrode model 404 includes various state variables and dynamic parameters. The state variables include voltages present at the anode 308 during operation of the battery cell, such as a negative electrode open-circuit voltage 702 (V_{OCV,N}), a negative electrode ohmic resistance 704 (V_{ohmic,N}) (i.e., a voltage loss at the negative electrode due to an ohmic resistance) and a negative electrode hysteresis voltage (V_{hys,N}) 706 The negative electrode ohmic resistance 704 is related to an ohmic resistance of the anode 308 and the negative electrode hysteresis voltage 706 results from hysteresis effects in the anode The dynamic parameters can represent a response of the anode 308 to an applied load. For illustrative purposes. the dynamic parameters are time constants represented by resistor-capacitor pairs 708, 710, 712.

A state of the electrochemical battery cell is determined by individually determining the state of the cathode 304 using the positive electrode model 402 and the state of the anode 308 using the negative electrode model 404. The battery model relates a state of lithiation of the battery (or of the cathode) to a terminal voltage of the battery. During charging, a state prediction model can be applied at the positive electrode model to predict a next state of the cathode at a next (k+1) time step based on the current (k) state variables and the charging operation. Various measurable parameters at the next time step are then predicted from the state variables. Measurements are then taken at the next time step and compared to the measurable parameters. The result of the comparison is used to update the positive electrode model of the next time step. This method can include the use of a Kalman filter. This method thus predicts a state of the cathode after the charging operation. The state prediction model can be used similarly on the negative electrode model to predict the state of the anode after the charging operation.

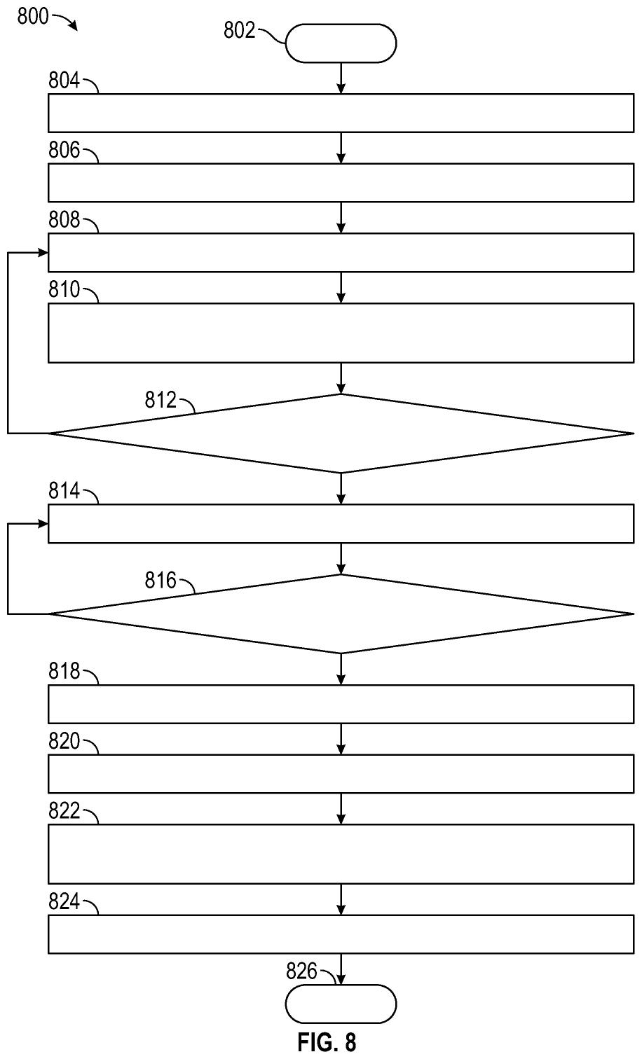

FIG. 8 is a flowchart 800 of a method of determining a voltage fade state of a battery cell after a charging operation, in an embodiment. The method begins at box 802. In box 802, the vehicle or system operating off of the battery cell can be in any state, including at rest, driving, discharging, etc. In box 804, data regarding the initial state of the battery cell is uploaded from a memory to a processor. The data includes an initial voltage fade state of the battery cell and electric models of the battery, including state variables and dynamic parameters of both the positive electrode model and the negative electrode model. In box 806, a charging process for the battery cell is commenced. In box 808, a terminal voltage of the battery is measured at one or more time steps of during the charging process. In box 810, the model of the battery (i.e., cathode and anode state variables and dynamic parameters) is updated using the prediction model over the one or more timesteps using the terminal voltage and the temperature. In box 812, the charging operation is monitored to determine whether charging is still ongoing or if the charging operation has ended.

If the charging operation is still ongoing, the method returns to box 808. Otherwise, the method proceeds to box 814.

In box 814, a cathode potential is measured after the charging operation is ended. In box 816, a timer is compared to a selected duration time, the time starts at zero when the charging operation is completed. If the timer is less than the selected duration time, the method returns to box 814 to obtain another measurement of cathode potential. Otherwise, if the selected duration time is over, the method proceeds to box 818.

In box 818, a maximum value of the cathode potential is determined from the cathode potential measurements obtained after the charging operation has ended. In box 820, a voltage fade state of the cathode is determined from the maximum cathode voltage V_{P,sense_max} and the updated model of the battery cell. In box 822, the lithiation state of the battery is updated based on the positive electrode open-circuit voltage (V_{OCV,P}) and the negative electrode open-circuit voltage (V_{OCV,N}). In box 824, the processor operates the vehicle based on the updated voltage fade state of the battery. Operating the vehicle can include limiting an amount of current supplied from the battery cell to the vehicle. The limit to the current can be based on the fade state and/or the state of lithiation of the battery cell. The method ends in box 826.

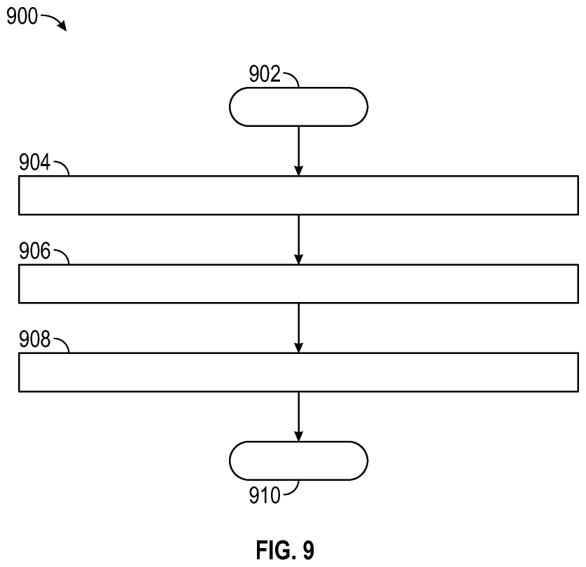

FIG. 9 is a flowchart 900 of a method for determining a voltage fade state of a battery cell from the maximum cathode voltage. Flowchart 900 is an expansion of the process performed in box 820 of FIG. 8. The method begins at box 902. In box 904, a peak voltage during charging is measured. In box 906, a voltage fade life modification is made based on the maximum charge reached at the end of the charging process. It is understood that the maximum charge at the end of the charging process is not necessarily 100%. Some users may charge to a lower state of charge, especially when charging using DC fast charging. In box 908, the voltage fade parameters for the open-circuit voltage V_{OCV,P} are updated using the voltage fade life modification. The method ends in box 910.

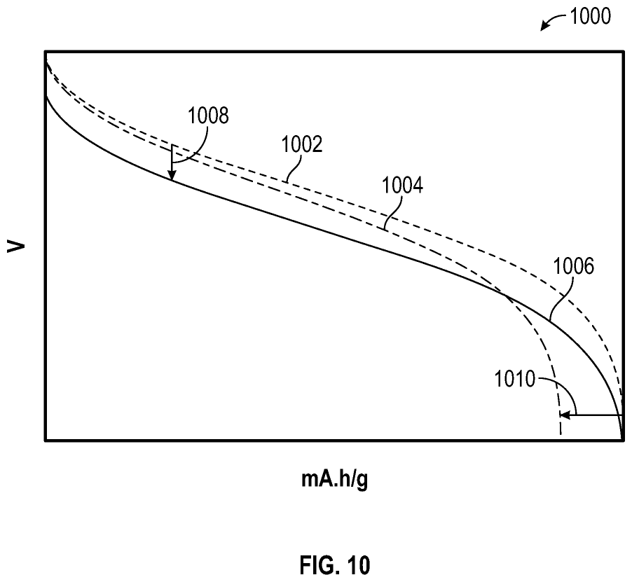

FIG. 10 shows a graph 1000 demonstrating a difference between a capacity fade and a voltage fade. Reversible capacity (indicative of lithiation state) is shown along the abscissa in milli-Amp-hours per gram (mAh/g) and cathode potential is shown along the ordinate axis in Volts (V). Curve 1002 shows a relation between cathode potential and reversible capacity for a battery at a beginning-of-life state. Curve 1004 shows the relation for a battery for which a capacity fade is present. Curve 1006 shows a relation for a battery for which a voltage fade is present. The voltage fade is due to structural changes impacting the energy of the active material of the battery during normal use of the battery, while the capacity fade is due to loss of accessibility to active material of the battery, often due to damage or overuse. The voltage fade is reflected in curve 1004 having lower voltage (indicated by voltage fade line 1008). The capacity fade is reflected in curve 1004 having less capacity density (indicated by capacity fade line 1010).

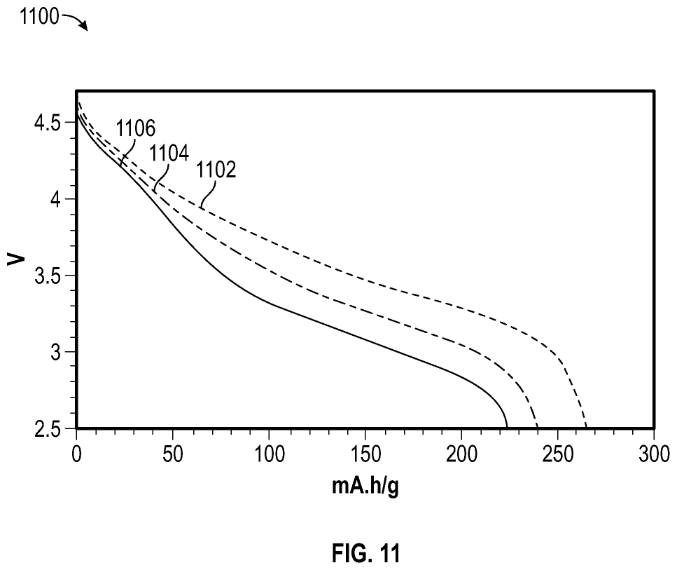

FIG. 11 shows a graph 1100 relating cathode potential to reversible capacity of the battery cell. Reversible capacity (indicative of lithiation state) is shown along the abscissa in milli-Amp-hours per gram (mAh/g) and cathode potential is shown along the ordinate axis in Volts (V). The curves shown in graph 1100 show a combination of both voltage fade and capacity fade. A first curve 1102 shows a relation between cathode potential and reversible capacity for a battery having a first fade state. A second curve 1104 shows a relation between cathode potential and reversible capacity for a battery having a second fade state. A third curve 1106 shows a relation between cathode potential and reversible capacity for a battery having a third fade state. The third fade state is greater than the second fade state, which is greater than the first fade state. In an illustrative embodiment, the voltage fade of the first curve 1102 is 0. The graph shows that the relation changes as the voltage fade state increases. The curves of graph 1100 can be used to determine the state of lithiation of the cathode from the maximum cathode voltage. This includes first determining the voltage fade state for the battery, selecting an appropriate curve for the voltage fade state and determining the lithiation state from the maximum cathode voltage using the selected curve.

The estimation of the state of lithiation can be performed at a voltage in which the selected curve is not too steep (i.e., is nearly non-differentiable). Thus, a suitable estimate can be obtained using voltages, for example, in the range of 3.5 V to 4.0 V. On the other hand, using a voltage of about 4.5 V employs a part of the curve that is highly vertical.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

When an element such as a layer, film, region, or substrate is referred to as being “on” another element, it can be directly on the other element or intervening elements may also be present. In contrast, when an element is referred to as being “directly on” another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A method of operating a vehicle, comprising:
obtaining an initial voltage fade state of a battery of the vehicle and a model of an initial state of the battery of the vehicle;
commencing a charging operation of the battery;
measuring a terminal voltage of the battery while charging;
updating the model of the battery during the charging operation using the terminal voltage;
ending the charging operation;
obtaining a plurality of measurements of a cathode voltage after the charging operation has ended;
determining a maximum cathode voltage from the plurality of measurements;
determining an updated voltage fade state of the battery based on the maximum cathode voltage;
selecting a relation between cathode voltage and lithiation state based on the updated voltage fade state;
calculating a state of lithiation of a cathode from the maximum cathode voltage using the selected relation; and
operating the vehicle based on the updated voltage fade state.

2. The method of claim 1, wherein the model further comprises a positive electrode model representative of a cathode of the battery and a negative electrode model representative of an anode of the battery, further comprising updating the positive electrode model and the negative electrode model during the charging operation.

3. The method of claim 2, further comprising determining an open-circuit voltage of the cathode from the terminal voltage and determining the lithiation state of the cathode from the open-circuit voltage of the cathode using the selected relation.

4. The method of claim 2, wherein one of the positive electrode model and the negative electrode model includes a state variable, the state variable including at least one of: (i) an open-circuit voltage; (ii) a hysteresis voltage; and (iii) an ohmic resistance.

5. The method of claim 4, wherein one of the positive electrode model and the negative electrode model includes a dynamic parameter, the dynamic parameter including a time constant indicative of a response of the battery to an applied load.

6. The method of claim 5, further comprising updating the state variable and the dynamic parameter using a Kalman filter.

7. The method of claim 1, wherein operating the vehicle further comprises limiting an amount of current supplied from the battery to the vehicle based on one of: (i) the updated voltage fade state; and (ii) the state of lithiation.

8. A system for operating a vehicle, comprising:
a processor configured to:
obtain an initial voltage fade state of a battery of the vehicle and a model of an initial state of the battery of the vehicle;
commence a charging operation of the battery;
measure a terminal voltage of the battery while charging;
update the model of the battery during the charging operation using the terminal voltage;
end the charging operation;
obtain a plurality of measurements of a cathode voltage after the charging operation has ended;
determine a maximum cathode voltage from the plurality of measurements;
determine an updated voltage fade state of the battery based on the maximum cathode voltage;
select a relation between cathode voltage and lithiation state based on the updated voltage fade state;
calculate a state of lithiation of a cathode from the maximum cathode voltage using the selected relation; and
operate the vehicle based on the updated voltage fade state.

9. The system of claim 8, wherein the model further comprises a positive electrode model representative of a cathode of the battery and a negative electrode model representative of an anode of the battery, further comprising updating the positive electrode model and the negative electrode model during the charging operation.

10. The system of claim 9, wherein the processor is further configured to determine an open-circuit voltage of the cathode from the terminal voltage and determining the lithiation state of the cathode from the open-circuit voltage of the cathode using the selected relation.

11. The system of claim 10, wherein one of the positive electrode model and the negative electrode model includes a state variable, the state variable including at least one of: (i) an open-circuit voltage; (ii) a hysteresis voltage; and (iii) an ohmic resistance.

12. The system of claim 11, wherein one of the positive electrode model and the negative electrode model includes a dynamic parameter, the dynamic parameter including a time constant indicative of a response of the battery to an applied load.

13. The system of claim 12, wherein the processor is further configured to update the state variable and the dynamic parameter using a Kalman filter.

14. The system of claim 8, wherein the processor is further configured to operate the vehicle by limiting an amount of current supplied from the battery to the vehicle based on one of: (i) the updated voltage fade state; and (ii) the state of lithiation.

15. A vehicle, comprising:
a processor configured to:
obtain an initial voltage fade state of a battery of the vehicle and a model of an initial state of the battery of the vehicle;
commence a charging operation of the battery;
measure a terminal voltage of the battery while charging;
update the model of the battery during the charging operation using the terminal voltage;
end the charging operation;
obtain a plurality of measurements of a cathode voltage after the charging operation has ended;
determine a maximum cathode voltage from the plurality of measurements;
determine an updated voltage fade state of the battery based on the maximum cathode voltage;
select a relation between cathode voltage and lithiation state based on the updated voltage fade state;
calculate a state of lithiation of a cathode from the maximum cathode voltage using the selected relation; and
operate the vehicle based on the updated voltage fade state.

16. The vehicle of claim 15, wherein the model further comprises a positive electrode model representative of a cathode of the battery and a negative electrode model representative of an anode of the battery, further comprising updating the positive electrode model and the negative electrode model during the charging operation.

17. The vehicle of claim 16, wherein the processor is further configured to determine an open-circuit voltage of the cathode from the terminal voltage and determining the lithiation state of the cathode from the open-circuit voltage of the cathode using the selected relation.

18. The vehicle of claim 17, wherein one of the positive electrode model and the negative electrode model includes a state variable, the state variable including at least one of: (i) an open-circuit voltage; (ii) a hysteresis voltage; and (iii) an ohmic resistance.

19. The vehicle of claim 15, wherein one of the positive electrode model and the negative electrode model includes a dynamic parameter, the dynamic parameter including a time constant indicative of a response of the battery to an applied load.

20. The vehicle of claim 19, wherein the processor is further configured to update the state variable and the dynamic parameter using a Kalman filter.
